(19) United States
(12) Patent Application Publication
(10) Pub. No.: US 2024/0404979 A1
(43) Pub. Date: Dec. 5, 2024

(54) WARPAGE CONTROL STRUCTURE FOR METAL BASE PLATE, SEMICONDUCTOR MODULE, AND INVERTER DEVICE

(71) Applicant: Mitsubishi Electric Corporation, Tokyo (JP)

(72) Inventors: Tatsuya KAWASE, Tokyo (JP); Kei HAYASHI, Tokyo (JP); Fumio WADA, Tokyo (JP); Atsushi MAEDA, Tokyo (JP)

(73) Assignee: Mitsubishi Electric Corporation, Tokyo (JP)

(21) Appl. No.: 18/806,198

(22) Filed: Aug. 15, 2024

Related U.S. Application Data
(63) Continuation of application No. 17/439,731, filed on Sep. 15, 2021.

(51) Int. Cl. H01L 23/00; H01L 25/065

(52) U.S. Cl. CPC H01L 24/32; H01L 23/562; H01L 25/0657; H01L 2224/32245; H01L 2924/3511

(57) ABSTRACT

The object is to provide a technology of controlling warpage of a metal base plate occurring in temperature change from high temperature to room temperature by causing warpage in the metal base plate in temperature change from room temperature to high temperature. A warpage control structure for a metal base plate 1 includes the metal base plate 1, a dissimilar metal layer 2, and an insulation substrate 4. The dissimilar metal layer 2 is formed on a surface of the metal base plate 1. The insulation substrate 4 is joined to a surface of the dissimilar metal layer 2 with a joining material 3 being provided between the insulation substrate 4 and the surface of the dissimilar metal layer 2, and includes metal plates 42a and 42b disposed on both surfaces. α1>α3>α2 is satisfied, where α1 represents a linear expansion coefficient of the metal base plate 1, α2 represents a linear expansion coefficient of the dissimilar metal layer 2, and α3 represents a linear expansion coefficient of the metal plates 42a and 42b.

### CROSS-REFERENCE TO RELATED APPLICATIONS

This application is a Continuation of U.S. patent application Ser. No. 17/439,731 filed Sep. 15, 2021, which is the U.S. National Stage of International Application No. PCT/JP2019/022519 filed Jun. 6, 2019, the entire contents of which are incorporated herein by reference.

### TECHNICAL FIELD

The present invention relates to a technology of controlling warpage occurring when an insulation substrate is joined to a metal base plate in a high temperature state.

### BACKGROUND ART

In a semiconductor module, a structure and a method of joining an insulation substrate to a metal base plate has been adopted. As a general joining method, inexpensive solder joining is in many cases used. However, when the insulation substrate is joined to the metal base plate using solder, warpage occurs in the metal base plate after joining. This is because of the following reason: In temperature change from room temperature to high temperature when solder is melted, warpage does not occur in the metal base plate, whereas in temperature change from high temperature to room temperature when the solder solidifies, significant warpage occurs in the metal base plate due to a difference of linear expansion coefficients between the metal base plate and the insulation substrate. In this case, if there is no initial warpage of the metal base plate, regarding the direction of the warpage after joining, the warpage in the metal base plate occurs in the direction projecting toward the side of a surface (hereinafter also referred to as an “insulation substrate joining surface”) thereof to which the insulation substrate is joined.

Subsequently, when an semiconductor element and electronical wiring are disposed on the insulation substrate and the semiconductor module is then assembled, warpage in a surface (hereinafter also referred to as a “non-joining surface”) of the metal base plate on the side opposite to the insulation substrate joining surface has importance. This is because a cooling fin or a water-cooling jacket is disposed on the non-joining surface of the metal base plate with grease being provided therebetween, and the warpage of the non-joining surface is thus closely related to cooling of the semiconductor module.

In this case, it is desirable that the warpage project toward the side opposite to the warpage projecting toward the side of the insulation substrate joining surface of the metal base plate, that is, that the warpage project toward the side of the non-joining surface of the metal base plate. When the semiconductor module is disposed in the cooling fin or the water-cooling jacket, the semiconductor module is generally fastened and fixed with a bolt or the like. If the warpage projects toward the side of the non-joining surface of the metal base plate, the warpage of the metal base plate can be corrected with an axial force of the bolt, and stable contact between the semiconductor module and the cooling fin or the water-cooling jacket can be achieved.

Warping treatment of causing initial warping in the metal base plate is generally performed in order to cause the warpage of the metal base plate to project toward the side of the non-joining surface; however, when there is a fin or the like in the non-joining surface of the metal base plate, performing the warping treatment is difficult.

In order to control warpage of a metal base plate, for example, Patent Document 1 discloses a method of reducing warpage of the metal base plate by applying metal of the same type as a metal plate of an insulation substrate to the surface of the metal base plate. Further, Patent Document 2 discloses a method of, in a base plate including a first metal layer made of copper and a second metal layer made of aluminum, setting the ratio of the thicknesses of the first metal layer and the second metal layer to 4:1. Further, Patent Document 3 discloses a method of, in a copper composite material heat dissipation substrate including a layer made of copper and a layer made of copper oxide, changing the ratio of copper and copper oxide to control warpage after sintering.

### PRIOR ART DOCUMENTS

### Patent Documents

Patent Document 1: WO 2015/029511
Patent Document 2: Japanese Patent Application Laid-Open No. 2013-062506
Patent Document 3: Japanese Patent Application Laid-Open No. 2003-046032

### SUMMARY

### Problem to be Solved by the Invention

However, by only applying the metal of the same type as the insulation substrate to the metal base plate as in the technology described in Patent Document 1, the warpage amount in temperature change from high temperature to room temperature after the insulation substrate is jointed to the metal base plate in the high temperature is larger than the warpage amount in temperature change from room temperature to high temperature in the metal applied to the metal base plate. Thus, the metal base plate has a shape projecting toward the side of the insulation substrate joining surface.

In the technology described in Patent Document 2, in order to enhance heat dissipation, the thickness of copper having high rigidity is dominant, and the thickness of aluminum having rigidity lower than that of copper is small, and thus the warpage amount in temperature change from room temperature to high temperature in the base plate is small.

The technology described in Patent Document 3 is for controlling warpage in a process of temperature change from high temperature to room temperature, and the warpage amount in temperature change from room temperature to high temperature in the copper composite material heat dissipation substrate is small.

In view of this, the present invention has an object to provide a technology of controlling warpage of a metal base plate occurring in temperature change from high temperature to room temperature by causing warpage in the metal base plate in temperature change from room temperature to high temperature.

### Means to Solve the Problem

A warpage control structure for a metal base plate according to the present invention includes: the metal base plate; a dissimilar metal layer formed on a surface of the metal base plate; and an insulation substrate joined to a surface of the dissimilar metal layer with a joining material being provided between the insulation substrate and the surface of the dissimilar metal layer, and including a metal plate disposed on both surfaces. α1>α3>α2 is satisfied, where α1 represents a linear expansion coefficient of the metal base plate, α2 represents a linear expansion coefficient of the dissimilar metal layer, and α3 represents a linear expansion coefficient of the metal plate.

### Effects of the Invention

According to the present invention, when the metal base plate is subjected to temperature change from room temperature to high temperature, due to the difference of the linear expansion coefficients between the metal base plate and the dissimilar metal layer, the metal base plate expands with respect to the dissimilar metal layer, and the metal base plate warps in the direction projecting toward the side opposite to the surface thereof to which the insulation substrate is joined. When the metal base plate and the insulation substrate are subjected to temperature change from high temperature to room temperature after the insulation substrate is jointed to the surface of the dissimilar metal layer with the joining material in this state, due to the difference of the linear expansion coefficients between the insulation substrate and the metal base plate, the metal base plate contracts with respect to the insulation substrate, and the metal base plate warps in the direction projecting toward the side of the surface thereof to which the insulation substrate is joined.

In the temperature change from room temperature to high temperature and the temperature change from high temperature to room temperature, the metal base plate warps in directions opposite to each other, and thus the warpage in each of the directions is cancelled out. In this manner, the warpage of the metal base plate occurring in the temperature change from high temperature to room temperature can be controlled.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a side view of a warpage control structure for a metal base plate according to an embodiment.

FIG. 2 is a side view illustrating a state in which the metal base plate is subjected to temperature change from room temperature to high temperature in the embodiment.

FIG. 3A is a side view illustrating a state immediately after an insulation substrate is joined to the metal base plate in a high temperature state in the embodiment and FIG. 3B is a side view illustrating the mounting of a semiconductor element.

FIG. 4 is a side view illustrating a state in which a metal base plate is subjected to temperature change from room temperature to high temperature in related art.

FIG. 5 is a side view illustrating a state immediately after an insulation substrate is joined to the metal base plate in a high temperature state in the related art.

FIG. 6 is a side view illustrating a state in which the metal base plate and the insulation substrate are subjected to temperature change from high temperature to room temperature in the related art.

### DESCRIPTION OF EMBODIMENTS

### Embodiment

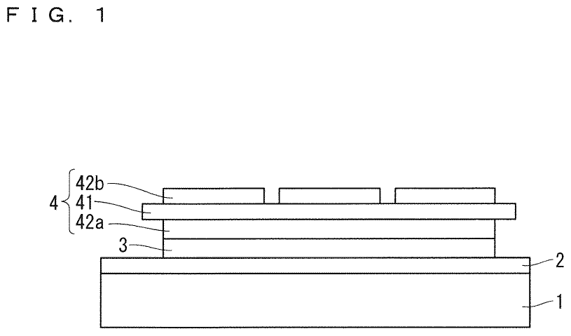

An embodiment of the present invention will be described below with reference to the drawings. FIG. 1 is a side view of a warpage control structure for a metal base plate according to an embodiment.

As illustrated in FIG. 1, the warpage control structure for the metal base plate constitutes a part of a semiconductor module, and includes a metal base plate 1, a dissimilar metal layer 2, and an insulation substrate 4.

The metal base plate 1 has a square shape of approximately 100 mm×100 mm in plan view, and has a thickness of from 3.5 mmt to 4.0 mmt. Further, as a material of the metal base plate 1, a highly thermally conductive material such as aluminum, aluminum alloy, or copper is desirable. In the present embodiment, aluminum is selected in order to reduce total weight.

The dissimilar metal layer 2 is formed on the entire surface of the metal base plate 1, or only in the region of the surface of the metal base plate 1 where the insulation substrate 4 is joined, and has a thickness of approximately 0.5 mmt. As a material of the dissimilar metal layer 2, a material having satisfactory wettability of the joining material 3 applied to join the insulation substrate 4 to the dissimilar metal layer 2 is desirable, and copper or nickel is desirable. In the present embodiment, nickel is selected. Examples of a method of forming the dissimilar metal layer 2 include the cold spray method and the metal application method.

The insulation substrate 4 is joined to the surface of the dissimilar metal layer 2, with the joining material 3 being provided therebetween. Although as the joining material 3, a brazing material, a solder, or the like is used, a solder is desirable in consideration of manufacturing costs and versatility. It is desirable that the thickness of the joining material 3 being a solder be from 0.2 mmt to 0.4 mmt, in view of heat dissipation. The back surface of the metal base plate 1, which is a surface on the opposite side of the surface on which the dissimilar metal layer 2 is formed, is attached to a cooling fin or a water-cooling jacket, with grease being provided therebetween. When the metal base plate 1 is attached to the water-cooling jacket, a pin fin or a straight fin may be formed on the back surface of the metal base plate 1, depending on a coolant.

The insulation substrate 4 has a square shape of approximately 70 mm×70 mm in plan view, and includes a ceramic substrate 41 and metal plates 42a and 42b. As a material of the ceramic substrate 41, an appropriate ceramic is selected out of ceramics such as alumina, AlN, and Si₃N₄, depending on an application. Note that, when warpage occurring at the time of assembly of the semiconductor module is large (500 μm or more), it is desirable that Si₃N₄ having high flexural strength be selected. In this case, depending on a withstand voltage for a working voltage, 0.32 mmt or 0.64 mmt is selected as the thickness of the ceramic substrate 41.

The metal plates 42a and 42b are formed on the back surface and the front surface of the ceramic substrate 41, respectively. Further, as a material of the metal plates 42a and 42b, aluminum or copper is generally used. However, in consideration of heat dissipation, it is desirable that copper be selected. In the present embodiment, copper is selected. Further, in consideration of heat dissipation and manufacturability, it is desirable that the thickness of copper be selected within the range of from 0.3 mmt to 0.8 mmt.

Here, in order that the warpage amount due to expansion of the metal base plate 1 in temperature change from room temperature to high temperature and the warpage amount due to contraction of the metal base plate 1 in temperature change from high temperature to room temperature be approximately equal to each other, the materials of the metal base plate 1, the dissimilar metal layer 2, and the metal plates 42a and 42b are selected so that α1>α3>α2 is satisfied, where α1 represents a linear expansion coefficient of the metal base plate 1, α2 represents a linear expansion coefficient of the dissimilar metal layer 2, and α3 represents a linear expansion coefficient of the metal plates 42a and 42b.

Next, effects of the warpage control structure for the metal base plate according to the embodiment will be described in comparison to a case of related art.

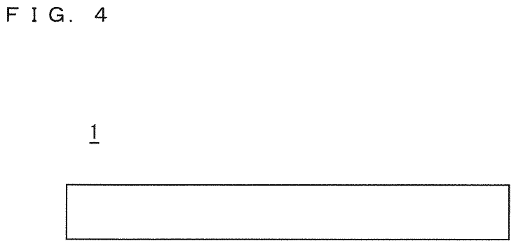

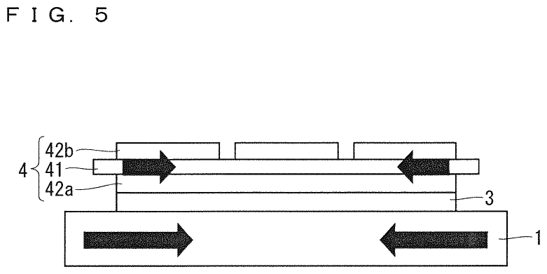

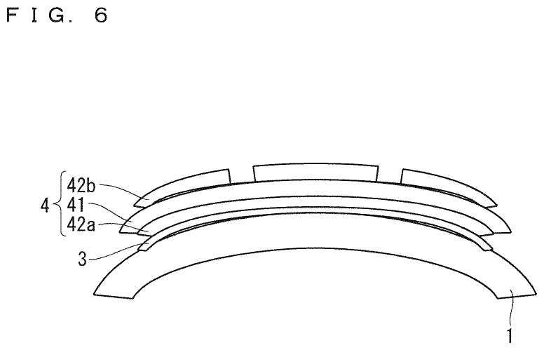

First, the case of the related art will be described. FIG. 4 is a side view illustrating a state in which the metal base plate 1 is subjected to temperature change from room temperature to high temperature in the related art. FIG. 5 is a side view illustrating a state immediately after the insulation substrate 4 is joined to the metal base plate 1 in the high temperature state in the related art. FIG. 6 is a side view illustrating a state in which the metal base plate 1 and the insulation substrate 4 are subjected to temperature change from high temperature to room temperature in the related art.

As illustrated in FIG. 4 and FIG. 5, in the related art, the dissimilar metal layer 2 is not formed on the surface of the metal base plate 1, and the insulation substrate 4 is joined to the surface of the metal base plate 1, with the joining material 3 being provided therebetween.

First, a temperature rising process, in which the temperature of the metal base plate 1 is changed from room temperature to high temperature, is performed. As illustrated in FIG. 4, in the temperature rising process, warpage does not occur in the metal base plate 1, and the metal base plate 1 remains flat.

Next, a joining process, in which the insulation substrate 4 is joined to the surface of the metal base plate 1 with the joining material 3 being provided therebetween in the high temperature state, is performed. As illustrated in FIG. 5, warpage does not occur in the metal base plate 1 immediately after the joining process, and the metal base plate 1 remains flat.

Next, a temperature falling process, in which the temperature of the metal base plate 1 is changed from high temperature to room temperature, is performed. In the temperature falling process, as indicated by the arrows of FIG. 5, the linear expansion coefficients of the metal base plate 1 and the insulation substrate 4 are different, and accordingly the contraction amounts of the metal base plate 1 and the insulation substrate 4 are different. Thus, as illustrated in FIG. 6, in the temperature falling process after joining, warpage occurs in the metal base plate 1 in the direction projecting toward the side of the surface thereof to which the insulation substrate 4 is joined. Note that the lengths of the arrows of FIG. 5 represent the contraction amounts of the metal base plate 1 and the insulation substrate 4.

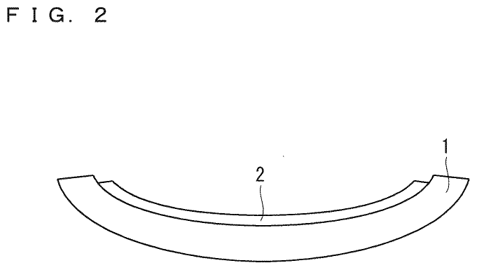

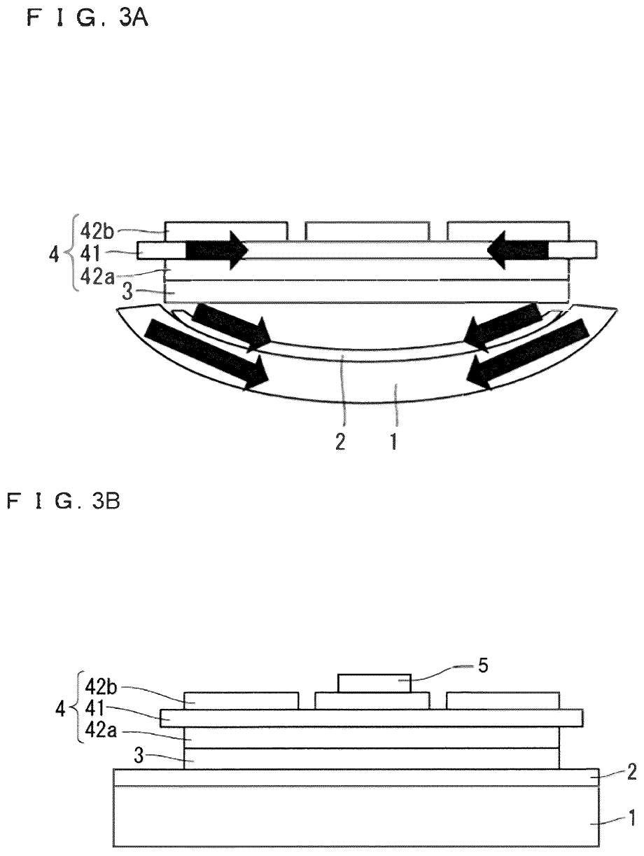

Next, a case of the embodiment will be described. FIG. 2 is a side view illustrating a state in which the metal base plate 1 is subjected to temperature change from room temperature to high temperature in the embodiment. FIG. 3A is a side view illustrating a state immediately after the insulation substrate 4 is joined to the metal base plate 1 in the high temperature state in the embodiment.

First, a temperature rising process, in which the temperature of the metal base plate 1 is changed from room temperature to high temperature, is performed. The linear expansion coefficients of the metal base plate 1 and the dissimilar metal layer 2 are different, and accordingly the expansion amounts of the metal base plate 1 and the dissimilar metal layer 2 are different. As illustrated in FIG. 2, in the temperature rising process, warpage occurs in the metal base plate 1 in the direction projecting toward the side opposite to the surface thereof to which the insulation substrate 4 is joined.

As illustrated in FIG. 3A, in the joining process performed subsequently, the insulation substrate 4 is joined to the surface of the dissimilar metal layer 2 with the joining material 3 being provided therebetween in the high temperature state. In this case, the metal base plate 1 is joined to the insulation substrate 4 in the state of warping in the direction projecting toward the side opposite to the surface thereof to which the insulation substrate 4 is joined. Further, immediately after the joining process, the warpage of the metal base plate 1 does not change.

In the temperature falling process after the joining process, as indicated by the arrows of FIG. 3A, the linear expansion coefficients of the metal base plate 1, the dissimilar metal layer 2, and the insulation substrate 4 are different, and accordingly the contraction amounts of the metal base plate 1, the dissimilar metal layer 2, and the insulation substrate 4 are different. Thus, warpage occurs in the metal base plate 1 in the direction projecting toward the side of the surface thereof to which the insulation substrate 4 is joined. As a result, as illustrated in FIG. 1, the metal base plate 1 becomes substantially flat. Note that the lengths of the arrows of FIG. 3A represent the contraction amounts of the metal base plate 1, the dissimilar metal layer 2, and the insulation substrate 4.

Here, table 1 shows simulation results of warpage in temperature change from room temperature (25° C.) to high temperature (250° C.) and temperature change from high temperature (250° C.) to room temperature (25° C.) when copper or nickel is selected as the dissimilar metal layer 2 in the present embodiment. As shown in table 1, it is understood that warpage after joining is more reduced in the case (embodiment) in which the linear expansion coefficient of the dissimilar metal layer 2 is set lower than the linear expansion coefficient of the metal plates 42a and 42b than in the case (comparative example) in which the linear expansion coefficients of the dissimilar metal layer 2 and the metal plates 42a and 42b are set equal.

TABLE 1

| | | | | \textcircled{1} WARPAGE | \textcircled{2} WARPAGE | |
|---|---|---|---|---|---|---|
| | | | METAL | AMOUNT OF | AMOUNT OF | |
| | | | PLATES | 1 + 2 IN | 1 + 2 + 4 IN | |
| | | | 42a AND | ROOM TEMPERATURE | HIGH TEMPERATURE | |
| | METAL | | 42b OF | → | → | |
| | BASE | DISSIMILAR | INSULATION | HIGH TEMPERATURE | ROOM TEMPERATURE | \textcircled{2} − |
| | PLATE 1 | METAL 2 | SUBSTRATE 4 | [mm] | [mm] | \textcircled{1} |
| COMPARATIVE | Al (α = 23 | Cu (α = 16.8 | Cu (α = 16.8 | 1,000 | 1,500 | 500 |
| EXAMPLE | ppm/° C.) | ppm/° C.) | ppm/° C.) | | | |
| EMBODIMENT | Al (α = 23 | Ni (α = 12.8 | Cu (α = 16.8 | 1,900 | 1,850 | −50 |
| | ppm/° C.) | ppm/° C.) | ppm/° C.) | | | |

Note that in the comparative example and the embodiment, the thickness of the metal base plate 1 is 4 mmt, the thickness of the dissimilar metal layer 2 is 0.5 mmt, and the thickness of each of the metal plates 42a and 42b is 0.4 mmt.

After the temperature falling process, mounting of a semiconductor element 5, wiring, attaching of a case, sealing with a gel or a resin, and the like are performed on a joined item, which is obtained by joining the insulation substrate 4 on the surface of the dissimilar metal layer 2 formed on the metal base plate 1 with the joining material 3 being provided therebetween in the high temperature state. In this manner, the semiconductor module is assembled. The semiconductor module is cooled with indirect cooling, which is disposed in the cooling fin, or with direct cooling, which is directly disposed in the water-cooling jacket, with grease or the like being provided therebetween. The semiconductor module is incorporated as a constituent component of an inverter device in a state of being disposed in the cooling fin or the water-cooling jacket.

As described above, the warpage control structure for the metal base plate 1 according to the embodiment includes the metal base plate 1, the dissimilar metal layer 2 formed on the surface of the metal base plate 1, and the insulation substrate 4 joined to the surface of the dissimilar metal layer 2 with the joining material 3 being provided between the insulation substrate 4 and the surface of the dissimilar metal layer 2, and including the metal plates 42a and 42b disposed on both the surfaces. α1>α3>α2 is satisfied, where α1 represents the linear expansion coefficient of the metal base plate 1, α2 represents the linear expansion coefficient of the dissimilar metal layer 2, and α3 represents the linear expansion coefficient of the metal plates 42a and 42b.

Thus, when the metal base plate 1 is subjected to temperature change from room temperature to high temperature, due to the difference of the linear expansion coefficients between the metal base plate 1 and the dissimilar metal layer 2, the metal base plate 1 expands with respect to the dissimilar metal layer 2, and the metal base plate 1 warps in the direction projecting toward the side opposite to the surface thereof to which the insulation substrate 4 is joined. When the metal base plate 1 and the insulation substrate 4 are subjected to temperature change from high temperature to room temperature after the insulation substrate 4 is jointed to the surface of the dissimilar metal layer 2 with the joining material 3 in this state, due to the difference of the linear expansion coefficients between the insulation substrate 4 and the metal base plate 1, the metal base plate 1 contracts with respect to the insulation substrate 4, and the metal base plate 1 warps in the direction projecting toward the side of the surface thereof to which the insulation substrate 4 is joined.

In the temperature change from room temperature to high temperature and the temperature change from high temperature to room temperature, the metal base plate 1 warps in directions opposite to each other, and thus the warpage in each of the directions is cancelled out. In this manner, the warpage of the metal base plate 1 occurring in the temperature change from high temperature to room temperature can be controlled.

The metal base plate 1 is made of aluminum or aluminum alloy, the dissimilar metal layer 2 is made of nickel, and the metal plates 42a and 42b are each made of copper. Thus, by adopting aluminum or aluminum alloy, which is inexpensive and has satisfactory thermal conductivity, for the metal base plate 1, heat dissipation of the semiconductor module and the inverter device can be enhanced. Further, by adopting nickel for the dissimilar metal layer 2, wettability of the joining material 3 can be secured. Further, although aluminum or copper is generally adopted for the metal plates 42a and 42b, copper is selected from the viewpoint of the linear expansion coefficient.

The joining material 3 is a solder, and thus by adopting a highly versatile solder for the joining material 3, costs for joining are reduced. Further, the warpage amount of the warpage in the metal base plate 1 in the direction projecting toward the side opposite to the surface thereof to which the insulation substrate 4 is joined in the temperature change from room temperature to high temperature and the warpage amount of the warpage in the metal base plate 1 in the direction projecting toward the side of the surface thereof to which the insulation substrate 4 is joined in the temperature change from high temperature to room temperature after joining of the insulation substrate 4 do not completely match. As there is a larger temperature difference between the room temperature and the high temperature, there is a larger difference of the warpage amounts. Accordingly, as there is a smaller temperature difference between the room temperature and the high temperature, a more desirable final shape is obtained in the joined item. Joining temperature of a solder is from 250° C. to 300° C., and temperature difference from room temperature is appropriate temperature, and thus a desirable final shape is obtained in the joined item.

The semiconductor module includes a warpage control structure for the metal base plate, and a semiconductor element 5 mounted on the surface of the insulation substrate 4, shown in FIG. 3B. Thus, by controlling warpage of the metal base plate 1, a yield of the semiconductor module can be enhanced. Further, the inverter device includes a semiconductor module. Accordingly, stable contact can be achieved between the semiconductor module and the cooling fin or the water-cooling jacket, and thus a yield of the inverter device can be enhanced.

While the invention has been shown and described in detail, the foregoing description is in all aspects illustrative and not restrictive. It is therefore understood that numerous unillustrated modifications can be devised without departing from the scope of the present invention.

Note that, in the present invention, the embodiment can be modified or omitted as appropriate within the scope of the invention.

### EXPLANATION OF REFERENCE SIGNS

1 Metal base plate, 2 Dissimilar metal layer, 3 Joining material, 4 Insulation substrate, 42a, 42b Metal plate.

1. A method of forming a warpage control structure for a metal base plate, the method comprising:
forming the metal base plate;
forming a dissimilar metal layer on a surface of the metal base plate; and
joining an insulation substrate to a surface of the dissimilar metal layer with a joining material being provided between the insulation substrate and the surface of the dissimilar metal layer, the insulation substrate including a ceramic substrate, an upper metal plate disposed on an upper surface of the ceramic substrate, and a lower metal plate disposed on a lower surface of the ceramic substrate, such that the upper metal plate and the lower metal plate are disposed on both surfaces of the ceramic substrate, the insulation substrate being joined to the joining material, the dissimilar metal layer, and the metal base plate in a high temperature state such that the metal base plate becomes substantially flat at a room temperature state, the high temperature state being between 250-300° C. and the room temperature state being around 25° C., wherein
α1>α3>α2 is satisfied, where α1 represents a linear expansion coefficient of the metal base plate, α2 represents a linear expansion coefficient of the dissimilar metal layer, and α3 represents a linear expansion coefficient of the upper metal plate and the lower metal plate, and
the warpage control structure is configured to substantially cancel out warpage in the metal base plate caused by temperature changes.

2. The method of forming the warpage control structure for the metal base plate according to claim 1, wherein
the metal base plate includes aluminum or aluminum alloy,
the dissimilar metal layer includes nickel, and
the upper metal plate and the lower metal plate include copper.

3. The method of forming the warpage control structure for the metal base plate according to claim 1, wherein
the joining material is a solder.

4. A method of forming a semiconductor module comprising:
forming the warpage control structure for the metal base plate according to the method of claim 1; and
mounting a semiconductor element on a surface of the insulation substrate.

5. A method of forming an inverter device comprising:
the semiconductor module formed according to the method of claim 4.

6. The method of forming the warpage control structure for the metal base plate according to claim 1, wherein
the metal base plate has a thickness between 3.5-4.0 mm,
the dissimilar metal layer has a thickness of about 0.5 mm, and
the upper metal plate and the lower metal plate each have a thickness between 0.3-0.8 mm.
